(19) United States
(12) Patent Application Publication
(10) Pub. No.: US 2002/0068462 A1
(43) Pub. Date: Jun. 6, 2002

(54) Method of etching a material layer and forming a lithography mask for use in manufacturing a microstructure

(76) Inventors: Dong-Wan Kim, Sungnam-City (KR); Yong-Beom Kim, Yongin-City (KR)

Correspondence Address: Mills & Onello, LLP, Eleven Beacon Street, Suite 605, Boston, MA, 02108, US

(21) Appl. No.: 09/513,796

(22) Filed: Feb. 25, 2000

(30) Foreign Application Priority Data
Aug. 3, 1999 (KR) 99-31860

(51) Int. Cl. H01L 21/302; H01L 21/461

(52) U.S. Cl. 438/745; 438/689

(57) ABSTRACT

A method of etching a material layer of a microstructure body, and a method of forming a lithography mask using the etching method are disclosed. In the method of etching a material layer, a carbon layer is formed on at least a part of the material layer to prevent the part of the material layer from being etched. The material layer is then etched using an alkali solution. In the lithography mask formation, an etch stop layer, a membrane layer, a lithography mask layer and a protective layer are sequentially formed on one surface of a substrate. Then, an etch mask including a carbon layer is formed on the other surface of the substrate, the etch mask exposing a part of the other surface of the substrate, and the other surface of the substrate, which is exposed by the etch mask, is etched using an alkali solution, so as to expose the membrane layer.

### BACKGROUND OF THE INVENTION

1. Field of the Invention

The present invention relates to a method of etching a material layer for use in manufacturing a microstructure body, and more particularly, to a method of manufacturing a lithography mask.

2. Description of the Related Art

Wet or dry etching is used to etch a material layer. Dry etching, such as that described in U.S. Pat. No. 5,022,959, is a method by which a material layer is selectively etched using a plasma etchant, resulting in a material layer pattern on a semiconductor substrate. Wet etching can be used to manufacture a microstructure body. The microstructure body can include a pattern of a material layer which constructs an integrated circuit. Wet etching can also be applied to forming a structure body for use in integrated circuit formation. For example, wet etching can be applied to forming a lithography mask such as a membrane mask, which is used for an X-ray lithography process or an electron beam lithography process. Wet etching can also be used to manufacture a microstructure system such as a microelectromechanical system (MEMS), in which an electrical circuit portion and a mechanical driving portion are integrated together. That is, wet etching can be applied to the bulk micromachining or surface micromachining fields.

In a process of manufacturing a lithography mask such as a membrane mask, wet etching, which uses an alkali solution as an etchant, is used to etch a substrate made of crystalline silicon. That is, a membrane layer and a lithography mask layer made of a heavy metal are formed sequentially on a crystalline silicon substrate, and the substrate is selectively etched, resulting in a substrate frame which supports the membrane layer and the lithography mask layer.

The etch rate of the substrate by an alkali solution varies depending on the crystal orientation of crystalline silicon. Based on such anisotropic etching characteristics, various silicon structure bodies having different shapes and sidewall profiles can be formed. In lithography mask manufacture, a crystalline silicon wafer having a crystal orientation in a surface direction of <100> or <110> is used as a substrate. The membrane layer is formed on one surface of the substrate, and an etch mask for selective etching is formed on the other surface of the substrate.

Usually, an etch mask is formed of a low-pressure silicon nitride (LP-SiNₓ). However, the etch mask may be formed of a silicon oxide (SiOₓ). The etch mask may remain after the substrate is selectively etched. However, in some cases, there is a need to remove the etch mask from the substrate. In order to remove a silicon nitride layer or a silicon oxide layer used as an etch mask, a hot phosphoric acid (H₃PO₄) or hydrofluoric acid (HF) solution is used. However, the hot H₃PO₄ or HF solution may corrode or damage other structural elements, for example, the substrate or material layers deposited on the other surface of the substrate, as well as the etch mask, thus causing failure to occur in the lithography mask.

### SUMMARY OF THE INVENTION

It is an object of the present invention to provide a method of etching a material layer for use in manufacturing a microstructure body, in which during an etch mask removing process which uses an alkali solution as an etchant, corrosion or damage to structural bodies or material layers other than an etch mask is prevented.

It is another object of the present invention to provide a method of manufacturing a lithography mask for use in a X-ray lithography process or electron beam lithography process, by using the material layer etching method used in forming a microstructure body.

According to an aspect of the present invention, there is provided a method of etching a material layer for use in manufacturing a microstructure body. In accordance with the method, the material layer is wet-etched using an alkali solution. A carbon layer is deposited on at least a part of the material layer to prevent the part of the material layer from being etched by the alkali solution.

In one embodiment, the material layer is formed of a crystalline silicon layer, and the alkali solution comprises at least one of a potassium hydroxide (KOH) solution, a sodium hydroxide (NaOH) solution, an ammonium hydroxide (NH₄OH) solution, a lithium hydroxide (LiOH) solution and a tetra methyl ammonium hydroxide (TMAH, (CH₃)₄NOH) solution. In one embodiment, after the material layer is etched, the carbon layer is removed by ashing.

In another embodiment, in etching a material layer for use in manufacturing a microstructure body, an etch mask is formed of a carbon layer on a material layer, which exposes a part of the material layer. The exposed surface of the material layer is selectively etched using the alkali solution.

In still another embodiment, in etching a material layer for use in manufacturing a microstructure body, an etch stop layer is formed of a carbon layer on an underlying layer, and then a material layer is formed on the carbon layer. Then, an etch mask which exposes a part of the material layer is formed on the material layer. The portion of the material layer exposed by the etch mask is etched up to the etch stop layer using an alkali solution.

According to another aspect of the present invention, there is provided a method of forming a lithography mask. According to the method, an etch stop layer, a membrane layer, a lithography mask layer and a protective layer are sequentially formed on one surface of a substrate. An etch mask is formed of a carbon layer on the other surface of the substrate, the etch mask exposing a part of the other surface of the substrate. The other surface of the substrate, which is selectively partially exposed by the etch mask, is etched using an alkali solution, so as to expose the membrane layer.

In one embodiment, the substrate is formed of a crystalline silicon layer, and the alkali solution comprises at least one of a potassium hydroxide (KOH) solution, a sodium hydroxide (NaOH) solution, an ammonium hydroxide (NH₄OH) solution, a lithium hydroxide (LiOH) solution and a tetra methyl ammonium hydroxide (TMAH, (CH₃)₄NOH) solution.

In one embodiment, the etch stop layer is formed of a carbon layer, and the protective layer is formed of a carbon layer. The lithography mask layer may be formed of a heavy metal such as tungsten (W) or tantalum (Ta).

In one embodiment, after the membrane layer is exposed, the protective layer is removed. Then the lithography mask layer is patterned. In one embodiment, the carbon layer used as the etch mask is removed by ashing.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic sectional view illustrating wet-etching on a material layer using a carbon layer as an etch mask according to one embodiment of the present invention.

FIG. 2 is a schematic sectional view illustrating wet-etching on a material layer using a carbon layer as an etch stop layer according to another embodiment of the invention.

FIG. 3 is a schematic sectional view illustrating wet-etching on a material layer using a carbon layer as a protective layer according to another embodiment of the present invention.

FIGS. 4 through 7 are schematic sectional views illustrating lithography mask formation according to an embodiment of the present invention.

### DESCRIPTION OF PREFERRED EMBODIMENTS

The present invention now will be described more fully with reference to the accompanying drawings, in which preferred embodiments of the invention are shown. In the drawings, the thickness of layers and regions are exaggerated for clarity. It will also be understood that when a layer is referred to as being “on” another layer or substrate, it can be directly on the other layer or substrate, or intervening layers may also be present.

According to the present invention, in a wet etching process in which an alkali solution is used as an etchant, a carbon layer can be used as an etch mask, an etch stop layer or a protective layer. An object to be wet etched may be a material layer formed on a substrate, or the substrate itself. For example, a crystalline silicon layer or a wafer formed of crystalline silicon can be used. Here, the alkali solution used in the wet-etching can include one or more of a potassium hydroxide (KOH) solution, a sodium hydroxide (NaOH), a lithium hydroxide (LiOH) solution, an ammonium hydroxide (NH₄OH) solution and a tetra methyl ammonium hydroxide (TMAH, (CH₃)₄NOH) solution.

In accordance with the invention, in order to selectively protect a part of material layer or a substrate from being removed by an alkali solution used as an etchant during a wet etching process, a carbon layer is used. For example, when a carbon layer is selectively formed on a part of a material layer or a part of the substrate, the material layer or the substrate can be protected by the carbon layer from corrosion or damage by the alkali solution during a wet-etching process.

After the wet etching process is completed, the carbon layer can be selectively removed by ashing with O₂ plasma. Unlike a conventional method where a hot H₃PO₄ solution or HF solution is used to remove an oxide silicon layer, silicon nitride layer or nitride layer, the O₂ plasma vaporizes and removes the carbon layer by breaking C—C bonds of the carbon layer. Thus, material layers or structure bodies other than the carbon layer are not corroded or damaged by the O₂ plasma during the wet etching process.

In the wet etching process using an alkali solution as an etchant, the carbon layer can be used as an etch mask, an etch stop layer which is used to detect an etch stop point, or a protective layer.

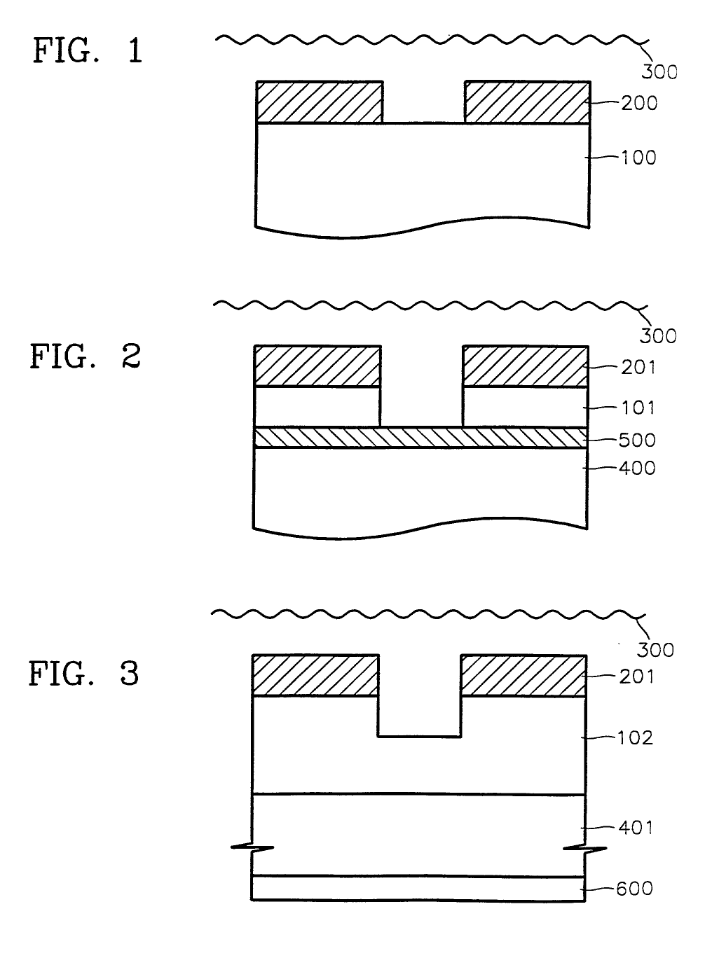

FIG. 1 is a sectional view illustrating wet-etching on a material layer using a carbon layer as an etch mask, in accordance with one embodiment of the present invention. In particular, a material layer 100, for example, a substrate formed of a crystalline silicon layer, is prepared. A carbon layer is formed on the material layer 100 by plasma enhanced chemical vapor deposition (PECVD). The carbon layer is formed as an etch mask 200, which exposes a part of the surface of the material layer 100. Then, the material layer 100, on which the etch mask 200 has been formed, is immersed in an alkali solution 300, wherein the surface of the material layer 100, which is not covered with the etch mask 200, is exposed to the alkali solution. The alkali solution 300 etches only the exposed surface of the material layer 100, and does not corrode the carbon layer. After the wet etching is completed, the carbon layer is oxidized by ashing, so that the etch mask 200 is selectively removed.

FIG. 2 is a sectional view illustrating wet-etching on a material layer by using a carbon layer as an etch stop layer, in accordance with another aspect of the invention. In particular, an etch stop layer 500 is formed of the carbon layer, between an underlying layer 400 and a material layer 101. A part of the material layer 101, which is exposed through an etch mask 201 formed on the material layer 101, is selectively corroded and removed by the alkali solution 300. As a result, the material layer 101 is patterned into a predetermined shape by the wet etching process. The wet-etching process can be stopped on the carbon layer 500 which serves as an etch stop layer 500. Also, an exposed part of the etch stop layer 500 can be selectively removed with O₂ plasma, so that the surface of the underlying layer 400 is selectively exposed.

FIG. 3 illustrates wet-etching on a material layer using a carbon layer as a protective layer, in accordance with another aspect of the invention. In particular, a material layer 102 formed on an underlying layer 401 is selectively wet etched using an etch mask 201. During the wet etch process, the bottom surface of the underlying layer 401, opposite to the contact surface with the material layer 102, may be exposed to the alkali solution 300 used as the etchant. This can potentially result in corrosion and/or damage to the layer 401. To prevent this, in accordance with the invention, a carbon layer 600 is applied as a protective layer to cover the bottom surface of the underlying layer 401. The protective layer 600 protects the bottom surface of the underlying layer 401 from the alkali solution 300, so that the corrosion or damage of the bottom surface of the underlaying layer 401 can be prevented. After the wet-etching process is completed, the protective layer 600 can be removed by ashing, without causing damage to other structural elements, for example, the material layer 102. By covering other structural elements which may be corroded or damaged by wet-etching with the protective layer 600 formed of a carbon layer, damage to the structural elements due to the alkali solution 300 can be prevented.

A process of forming a microstructure body using the carbon layer as an etch mask, an etch stop layer or a protective layer, will be described in detail in reference to manufacture of a lithography mask for use in a lithography process.

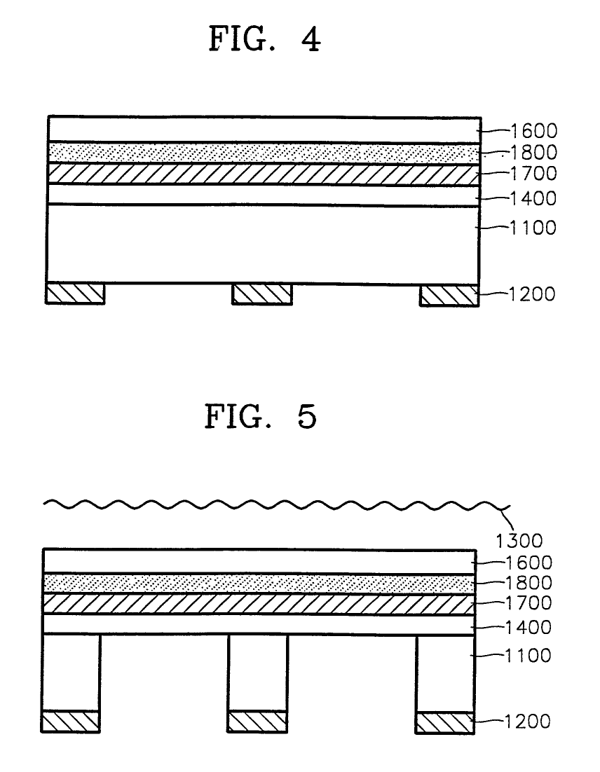

FIGS. 4 through 7 are schematic sectional views illustrating lithography mask manufacture according to an embodiment of the present invention. A lithography mask for an X-ray lithography process or electron beam lithography process includes a lithography mask layer made of a heavy metal, which is formed on a membrane layer, and a structure body which supports the membrane layer. In one embodiment, a substrate or wafer formed of crystalline silicon is used as the structure body for supporting the membrane layer. When patterning the substrate into the structure body for supporting the membrane layer, wet-etching using an alkali solution as an etchant is carried out. In the present embodiment, an etch mask, an etch stop layer or a protective layer, which are important in etching a substrate, is formed of a carbon layer.

FIG. 4 is a schematic sectional view illustrating formation of an etch mask 1200 on a substrate 1100. In particular, a carbon layer is deposited on one surface of the substrate formed of, for example, crystalline silicon, to form the etch mask 1200 which exposes a part of the substrate 1100. In one particular exemplary embodiment, the carbon layer can be deposited using a PECVD apparatus operating at a radio frequency (RF) of about 380 kHz. The carbon layer can be deposited on the substrate 1100 in a chamber under a pressure of 460 mTorr, by supplying methane (CH₄) gas as a carbon source gas at a flow rate of about 300 standard cubic centimeter per minute (sccm). Here, the carbon layer is deposited with a power of 500 watts at about 200° C. for about 4 minutes. The deposition conditions can be varied depending on the thickness or characteristics of the carbon layer.

Before forming the etch mask 1200 of the carbon layer, multiple material layers can be formed on a surface of the substrate 1100, opposite to the surface of the substrate 1100 on which the etch mask 1200 is to be formed. For example, an etch stop layer 1400, a membrane layer 1700, a lithography mask layer 1800 and a protective layer 1600 can be sequentially deposited as shown in FIG. 4.

The etch stop layer 1400 can be formed of a carbon layer on the substrate 1100 using the PECVD described above. The membrane layer 1700, which transmits X-rays or electron beams, is formed on the etch stop layer 1400. Substantially, the membrane layer 1700 is formed of a carbon carbide (SiC) layer or a silicon nitride (SiN) layer to a thickness of 2-3 μm.

The lithography mask layer 1800 is formed on the membrane layer 1700 to a predetermined thickness. The lithography mask layer 1800 is formed of a material which selectively blocks X-rays or electron beams which have passed through the membrane layer 1700, The lithography mask layer 1800 selectively shields X-rays or electron beams so as to transfer a pattern image for a desired integrated circuit on the substrate. For example, a heavy metal such as tungsten (W) and tantalum (Ta) is used as a material for the lithography mask layer 1800.

In addition, the protective layer 1600 is formed over the lithography mask layer 1800. The protective layer 1600 protects the lithography mask layer 1800 from being corroded or damaged by an alkali solution used for etching the substrate 1100 and the like. The protective layer 1600 can also be formed of a carbon layer.

The substrate 1100 is selectively etched using the alkali solution. That is, the resultant structure body is immersed in the alkali solution, which permits the alkali solution to react on the surface of the substrate 1100, which is exposed by the etch mask 1200.

FIG. 5 is a schematic sectional view illustrating etching of the substrate 1100 exposed by the etch mask 1200. In particular, the exposed substrate 1100 is immersed in the alkali solution 1300 so as to corrode the substrate 1100 via a reaction of the alkali solution on the exposed part of the substrate 1100. The alkali solution 1300 may include one or more of a KOH solution, a NaOH solution, a LiOH solution, a NH₄OH solution and TMAH solution.

Substantially, the carbon layer used as the etch mask 1200 is barely corroded by the alkali solution 1300. This result was ascertained in an experimental example. That is, when a silicon wafer on which a carbon layer had been deposited to a thickness of 600 Å was immersed in a 40 wt % KOH solution at 70° C. for several hours, the carbon layer remained, i.e., it was not corroded or etched by the alkali solution. Also, when the same silicon wafer having the carbon layer was left in a 20 wt % TMAH solution at 80° C. for several hours, the carbon layer was not corroded. Thus, since corrosion of the carbon layer used as the etch mask 1200 by the alkali solution 1300 barely occurs, the substrate 1100 can be selectively etched.

In the case where the substrate 1100 is a material layer formed of crystalline silicon, anisotropic etching can be performed due to the different etch rate depending on the crystal orientation of the crystalline silicon. In particular, the etch rates in surface, directions (100) and (110) are higher than that in the surface direction (100). Thus, when a silicon wafer having the surface direction of (100) is used as the substrate 1100, a sidewall exposed by etching has the surface direction (111). Also, when a silicon wafer having the surface direction of (110) is used as the substrate 1100, a sidewall exposed by the etching has the surface direction (111). Due to the anisotropic etching, a good sidewall profile can be obtained using crystalline silicon.

The anisotropic etching can be stopped by the etch stop layer 1400. For example, the etching is continued until the etch stop layer 1400 is exposed. Alternatively, the membrane layer 1700 itself may acts as an etch stop layer. In such cases, the formation of the etch stop layer 1400 may be omitted.

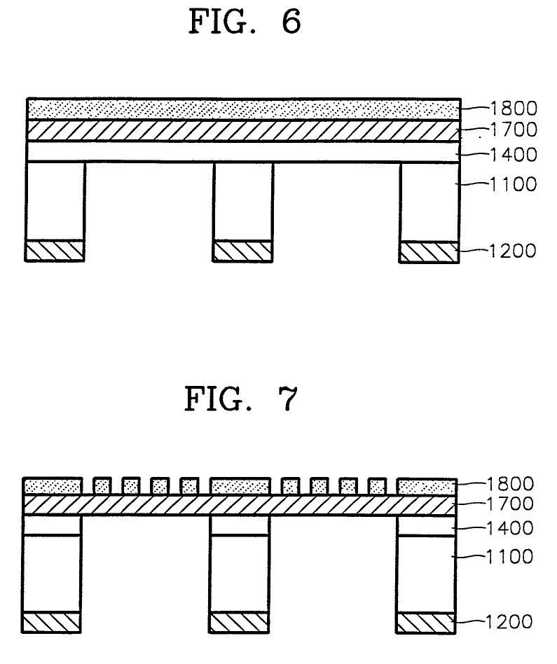

FIG. 6 is a schematic sectional view illustrating etching of the etch stop layer 1400 so as to expose the membrane layer 1700. In particular, the remaining etch stop layer 1400 is removed by etching, to expose the membrane layer 1700. For the removal of the etch stop layer 1400, a wet etching technique is adopted. However, in the case where the etch stop layer 1400 is formed of a carbon layer, an exposed part of the carbon layer can be selectively removed using O₂ plasma, so that the membrane layer 1700 is exposed. Substantially, the membrane layer 1700 is not damaged by the O₂ plasma. This is because the membrane layer 1700 is formed of a SiC or SiN layer. Thus, substantially, only the etch stop layer 1400 formed of a carbon layer can be selectively removed.

In the case where the membrane layer 1700 acts as an etch stop layer, so that the formation of the etch stop layer 1400 is not required, the remaining silicon is completely removed by over etching, thereby fully exposing the membrane layer 1700.

Then, the protective layer 1600 (see FIG. 4) which covers the lithography mask layer 1800 is removed. When the protective layer 1600 is formed of a carbon layer, the protective layer 1600 can be selectively removed via ashing using the O₂ plasma. In such a case, substantially no damage is caused to other structural bodies, for example, the membrane layer 1700 or the substrate 1100, which is formed below the lithography mask layer 1800.

FIG. 7 is a schematic sectional view illustrating a step of removing the lithography mask layer 1800. In particular, after the protective layer 1600 is removed, the exposed lithography mask layer 1800 is appropriately patterned for a desired pattern. That is, a part of the lithography mask layer 1800, which blocks the transmission of X-rays or electron beams is maintained, while the other part of the lithography mask layer 1800 which allows the transmission of X-rays or electron beams is selectively removed.

Since the etch mask 1200 is formed of a carbon layer, the etch mask 1200 can be selectively removed via ashing using the O₂ plasma. In the case where the protective layer 1600 or the etch stop layer 1400 is also formed of a carbon layer, the etch mask 1400 can be removed together with the protective layer 1600 or the etch stop layer 1400. Alternatively, the etch mask 1400, and the protective layer 1600 or the etch stop layer 1400 may be separately removed. Also, since the etch mask 1200 is formed of a carbon layer, the etch mask 1200 can be selectively removed by the O₂ plasma, without causing damage to the substrate 1100, the membrane layer 1700 or the lithography mask layer 1800.

In the conventional case, because an etch mask is formed of a silicon oxide or silicon nitride layer, it is difficult for the etch mask to be selectively etched with respect to a membrane layer formed of a silicon carbide, silicon nitride or nitride layer. In other words, the membrane layer formed of a silicon carbide, silicon nitride or nitride layer may be corroded by an etchant used for etching the etch mask formed of a silicon oxide or silicon nitride, for example, by a hot H₃PO₄ or HF solution.

However, in the present invention, the etch mask and other layers can be formed of a carbon layer, so that the O₂ plasma is used, instead of the hot H₃PO₄ or HF solution, to remove the etch mask and other layers. Thus, the damage to the membrane layer can be prevented. Also, other structural elements of the lithography mask are barely damaged by the hot H₃PO₄ or HF solution.

As described above, in the preferred embodiments, the present invention forms the etch mask, the etch stop layer or the protective layer, of a carbon layer, which is not etched during a wet etching process using an alkali solution as an etchant, and such a carbon layer can be removed by ashing using O₂ plasma, without causing damage to other structural elements.

Although the preferred embodiments are described in reference to the lithography mask for use in a lithography process using X-rays or electron beams, it is appreciated that the spirit of the present invention may be extended to the fields relating to bulk micromachining or surface micromachining, for example, to a process of forming a microstructure body by etching a crystalline silicon layer using an alkali solution.

As described above, the present invention utilizes a carbon layer as the etch mask, the etch stop layer or the protective layer in a wet-etching process using an alkali solution. Also, since the carbon layer can be selectively removed with respect to other structural elements via ashing, other structural elements are protected during the removal of the carbon layer without damage. Also, the carbon layer can be used as an etch mask in manufacturing a lithography mask. Since the carbon layer can be selectively removed by ashing, damage to other structural elements, for example, a membrane layer, during an etch mask removing process can be prevented.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A method of etching a material layer, comprising:
forming a carbon layer on at least a part of the material layer to prevent the part of the material layer from being etched; and
wet-etching the material layer using an alkali solution.

2. The method of claim 1, wherein the material layer is formed of a crystalline silicon layer.

3. The method of claim 1, wherein the alkali solution comprises at least one solution selected from the group consisting of a potassium hydroxide (KOH) solution, a sodium hydroxide (NaOH) solution, an ammonium hydroxide (NH₄OH) solution, a lithium hydroxide (LiOH) solution and a tetra methyl ammonium hydroxide (TMAH, (CH₃)₄NOH) solution.

4. The method of claim 1, wherein the carbon layer is used as an etch mask formed on the top surface of the material layer, said etch mask exposing a part of the top surface of the material layer to permit the alkali solution to etch the exposed part of the material layer.

5. The method of claim 4, further comprising, after the step of etching the material layer, removing the carbon layer via ashing.

6. The method of claim 1, further comprising:
before etching the material layer, forming an underlying layer underneath the material layer; and
before etching the material layer, forming an etch mask on the top surface of the material layer, said etch mask exposing a part of the top surface of the material layer to permit the alkali solution to etch the exposed part of the material layer,
wherein the carbon layer is formed between the underlying layer and the material layer and is used as an etch stop layer.

7. The method of claim 1, further comprising:
before etching the material layer, forming an underlying layer underneath the material layer; and
before etching the material layer, forming an etch mask on the top surface of the material layer, said etch mask exposing a part of the top surface of the material layer to permit the alkali solution to etch the exposed part of the material layer,
wherein the carbon layer is formed over a surface of the underlying layer which does not contact the material layer, and is used as a protective layer for preventing the surface of the underlaying layer from being etched by the alkali solution.

8. A method of etching a material layer, comprising:
forming an etch mask on a material layer, said etch mask including a carbon layer and exposing a part of the material layer; and
selectively etching the exposed surface of the material layer using an alkali solution.

9. The method of claim 8, wherein the material layer is formed of a crystalline silicon layer.

10. The method of claim 8, wherein the alkali solution comprises at least one solution selected from the group consisting of a potassium hydroxide (KOH) solution, a sodium hydroxide (NaOH) solution, an ammonium hydroxide (NH₄OH) solution, a lithium hydroxide (LiOH) solution and a tetra methyl ammonium hydroxide (TMAH, (CH₃)₄NOH) solution.

11. A method of etching a material layer, comprising:
forming an etch stop layer including a carbon layer on an underlying layer;
forming a material layer on the carbon layer;
forming on the material layer an etch mask which exposes a part of the material layer; and
etching the material layer which is exposed by the etch mask, up to the etch stop layer, using an alkali solution.

12. A method of etching a material layer, comprising:
forming a material layer on an underlying layer;
etching the material layer using an alkali solution; and
forming a protective layer including a carbon layer over a surface of the underlying layer that does not contact the material layer, the protective layer preventing the surface of the underlaying layer that does not contact the material layer from being etched by the alkali solution.

13. A method of forming a lithography mask, comprising:
forming an etch stop layer, a membrane layer, a lithography mask layer and a protective layer over one surface of a substrate;
forming an etch mask including a carbon layer on another surface of the substrate, the etch mask exposing a part of the other surface of the substrate, and
etching the other surface of the substrate using an alkali solution to expose the membrane layer.

14. The method of claim 13, wherein the substrate is formed of a crystalline silicon layer.

15. The method of claim 13, wherein the alkali solution comprises at least one solution selected from the group consisting of a potassium hydroxide (KOH) solution, a sodium hydroxide (NaOH) solution, an ammonium hydroxide (NH₄OH) solution, a lithium hydroxide (LiOH) solution and a tetra methyl ammonium hydroxide (TMAH, (CH₃)₄NOH) solution.

16. The method of claim 13, wherein the etch stop layer is formed of a carbon layer.

17. The method of claim 13, wherein the protective layer is formed of a carbon layer.

18. The method of claim 13, wherein the lithography mask layer is formed of a heavy metal selected from the group consisting of tungsten (W) and tantalum (Ta).

19. The method of claim 13, further comprising:
after exposing the membrane layer, removing the protective layer; and
after exposing the membrane layer, patterning the lithography mask layer.

20. The method of claim 13, further comprising, after exposing the membrane layer, removing the carbon layer used as the etch mask via ashing.
